(19) United States
(12) Patent Application Publication
(10) Pub. No.: US 2021/0251204 A1
(43) Pub. Date: Aug. 19, 2021

(54) Subsea Light Emission

(71) Applicant: SafetyNet Technologies, London (GB)

(72) Inventors: Aran Kumar DASAN, London (GB); Steven OGBORNE, London (GB); Daniel Nicholas WATSON, London (GB)

(21) Appl. No.: 17/252,067

(22) PCT Filed: Jun. 17, 2019
(86) PCT No.: PCT/GB2019/051669

§ 371 Date: Dec. 14, 2020

(30) Foreign Application Priority Data
Jun. 15, 2018 (GB) 1809883.0

(51) Int. Cl. A01K 75/02; A01K 97/00; H05B 47/175; H05B 47/105; H05K 5/06; H05K 5/00; H02J 7/02

(52) U.S. Cl. CPC A01K 75/02; A01K 97/00; H05B 47/175; H05B 45/10; H05K 5/069; H05K 5/0086; H02J 7/02; H05B 47/105

(57) ABSTRACT

A light emitting device 100, 200, 500 for a subsea environment has at least one light source and a power source. The device further comprises a housing 110 having a first housing portion 110a, wherein the at least one light source and the power source are enclosed within the first housing portion and a second housing portion 110b comprising a fluid-tight seal for the housing. A system 400, 600 is also provided comprising a plurality of light emitting devices.

### FIELD OF THE INVENTION

The present invention relates to a light emitting device for a subsea environment.

### BACKGROUND

Depleting fish stocks and penalties applied to fishing vessels that catch juvenile fish or adult fish of threatened species (i.e., species of fish with a low population which threatens the survival of the species) means that there is a need for methods of catching fish in a sustainable and selective way, resulting in fewer juvenile or threatened fish being caught in fishing gear (e.g., nets, pots, traps, fishing lines) or alternatively an increase in the capture of target fish species.

Current fishing gear does not enable fishing crews to conduct fishing operations in a species selective way, meaning that they may frequently catch non-target species). Non-target species can be classified as economic (e.g., low price or no market to sell to) or regulatory (e.g., illegal to land, protected species, no legal quota) bycatch, and are undesirable in either case. In known methods, escape rings may be fitted to fishing devices that provide an aperture large enough for a juvenile fish to swim through, but not large enough for adult fish to swim through.

### SUMMARY

The inventor has appreciated that behaviour of fish and other ocean organisms such as crustaceans, seabirds and marine mammals can be influenced and/or controlled by the use of light stimuli, and that this may be used to aid in providing selective fishing methods.

According to a first aspect of the invention, there is provided a light emitting device for a subsea environment.

The device may comprise at least one light source. The device may also comprise a power source. The power source may be wirelessly chargeable. The device may further comprise a housing. The housing may comprise a first housing portion. The at least one light source and the power source may be enclosed within the first housing portion. The housing may further comprise a second housing portion. The second housing portion may provide and/or comprise a fluid-tight seal for the housing.

Such a housing may enable the light emitting device to be mechanically suitable for use in a subsea environment, and optionally wirelessly chargeable. By providing a first housing portion enclosing the lighting components, and a second housing portion comprising a fluid-tight seal for the housing, the first housing portion may be configured to act as a pressure vessel independently of the second housing portion sealing the housing. In this way, deformation of the first housing portion under pressure may not affect or compromise the integrity of the seal provided by the second housing portion. The sealing structure of the second housing portion may be more robust if deflections or deformations in the second housing portion are minimised or eliminated. The device may be configured to selectively emit light through the first housing portion and/or the second housing portion.

Furthermore, by separating the sealing structure from the pressure vessel structure, the first housing portion may deform to a greater extent than would ordinarily be acceptable for a pressure vessel designed for a similar subsea environment. Greater deformation may be achieved without compromising the sealing structure and potentially causing fluid ingress into the first housing portion. The first housing portion may therefore not be required to be as rigid (and/or therefore as large and/or heavy) as a typical pressure vessel designed for a similar subsea environment.

For example, in a typical cylindrical pressure vessel, deflections in the seal surface of less than 1 mm can compromise the watertight seal, whereas cylinder wall deflections can be up to or more than an order of magnitude larger than 1 mm before structural collapse of the cylinder wall occurs. If the cylinder wall must be rigid enough to ensure safe deflections in the watertight seal then it will be stiffer, and therefore thicker than it needs to be.

Pressure vessels with smaller radii are able to withstand the same pressures as pressure vessels with larger radii, whilst utilising thinner walls than required in pressure vessels with larger radii. The circumferential stress for a thin walled cylinder is given by the equation σ=Pr/t, where σ is the circumferential stress, P is the external pressure, r is the cylinder radius and t is the wall thickness. As can be seen, for the same target pressure and maximum wall stress, that wall thickness is proportional to cylinder radius. To optimise for thin walls, a correspondingly smaller radius must be used. The mass and dimensions of the device may therefore be reduced whilst remaining suitable for use in a subsea environment.

The first housing portion may therefore comprise walls thin enough to enable efficient wireless charging of the light emitting device, whilst still enabling the light emitting device to withstand substantial pressures experienced in a subsea environment. For example, a charging coil receiver of 30 mm×40 mm will not function satisfactorily (or at all) when at a distance of greater than 10 mm from a transmitting charging coil. In this instance, a housing wall thickness of 5 mm or less would be required to charge at an optimum power transfer. For this reason, thin walled devices have traditionally not been used in subsea environments, due to the difficulties normally experienced due to the increased pressure.

Wireless charging of the light emitting device may simplify interaction of a user with the device. Wireless charging may also increase the speed of interaction of the user with the device (i.e., the time spent interacting with the device to charge the device may be reduced). For example, wireless charging may remove the requirement for wired connections to be provided on the device.

Wireless charging may also remove the need for the user to open the device. In this way, the housing may significantly reduce the risk of electronic components contained within the first housing portion being exposed to water due to incorrect closing of the light emitting device after maintenance (e.g., replacing batteries or other components) or charging. Furthermore, battery waste from disposable batteries that may otherwise be used to provide power to the light emitting device is significantly reduced.

By removing the need for wired connections or the need to gain access to the interior of the device, the mechanical design of the device may also be improved and/or simplified, exemplified by the housing described above. Mechanical wear of the device may therefore also be reduced, resulting in a longer product lifespan. Furthermore, removing the need for the device to be opened for access means that any physical tampering may be evident. It may be possible to associate an identity code with the device (e.g., by hardcoding an identity code into firmware operating the device), meaning that devices may be traced to owners if lost at sea.

The housing structure enabling the first housing portion to comprise walls thin enough for wireless charging may also enable the light emitting device to efficiently dissipate heat through the first housing portion. For example, walls as thin as 5 mm may be used. Conductive heat flux through a substrate is defined by the relationship q=−k·dT/dx, where q is the heat flux, k is the thermal conductivity of the material, dT is the temperature difference through the thickness of the substrate and dx is the distance through the thickness of the substrate. Thinner walls create a greater temperature gradient which creates a greater heat flux out of the device. Similarly, the first housing portion may comprise walls thin enough to improve transmission of light emitted by the at least one light source to the subsea environment.

The housing may be formed of two or more housing components configured to mutually engage with each other. The housing may comprise two or more components (e.g. two halves) which, when joined, mated or placed together form the whole housing. In a preferred embodiment, there are two housing components or shells. Each housing component may comprise a part (e.g. approximately half) of the first and second housing portions. The housing components join, mate or otherwise locate together along a longitudinal axis or plane of the housing: the housing portions define transverse sections of the housing (i.e. perpendicular to the longitudinal axis/plane). The first and second housing portion parts in each housing component may be integrally formed (i.e. a one-piece construction) or formed of separate housing portion parts.

A seal may be provided that is configured to engage with the first and/or second housing component to seal the housing components together to form the housing. The housing components may be substantially planar components and may be substantially circular in shape. The seal may be substantially a ring that locates around the exterior/circumference of the housing portions. The seal may engage with and/or overlap with the first and/or second housing component. The device may be configured to selectively emit light through one/both of the housing components (the upper half and/or the lower half of the housing).

One or more of the at least one light sources may be configured to emit light at one or more wavelengths.

The device may comprise a means for selecting output parameters (such as light intensity, light colour, light emission duration etc.) defining emission of light from the device based on one or more input parameters input to the device by a user. The input parameters may be selected from one or more species of fish or other ocean organisms to be targeted and expected fishing conditions. Expected fishing conditions may include but are not limited to expected fishing depth and expected ambient light levels at an expected fishing depth.

The light emitting device may further comprise a light source controller configured to control the emission of light from the at least one light source. The device may further comprise a memory configured to store instructions for controlling emission of light from the at least one light source. The light source controller may be configured to control the emission of light from the at least one light source based on stored instructions. The light source controller and the memory may be enclosed within the first housing portion.

Customisability of the emission of light from the at least one light source for different subsea environments may enable a more effective lure for selectively catching adult fish rather than juvenile fish. Altering light emission from the at least one light source may enable particular species of ocean organisms to be targeted. For example, scientific hypotheses related to the use of different kinds of light to influence fish behaviour in the commercial fishing process may be tested, improving sustainability outcomes by reducing bycatch of undesirable species.

In an aspect or embodiment, the instructions may specify one or more species of fish to be targeted and one or more expected fishing conditions. The one or more expected fishing conditions may include expected fishing depth and expected ambient light levels at the expected fishing depth. The device may further comprise a selection algorithm stored in the memory. The selection algorithm may be configured to select output parameters of the light to be emitted from the light emitting device (e.g. light intensity, light colour, light emission duration) based on the instructions. The selection algorithm may be configured to select output parameters of the light to be emitted from the light emitting device, based on the instructions, from a database, stored in the memory, of pre-determined optimal output parameters specifying output parameters in relation to pre-determined combinations of species of fish to be targeted and expected fishing conditions.

The device may be configured to receive instructions from a user device via wired or wireless communication. The device may be configured to receive instructions from a user device via infrared communication.

Marine and subsea environments are typically harsh environments for radio frequency communications, as, for example, strong electromagnetic waves may be emitted from nearby radar antenna. Such electromagnetic waves may cause interference with radio frequency communication used to communicate instructions to devices. By instead utilising infrared communication, a more robust medium for communication of instructions in a subsea environment may be achieved, avoiding interference with radio frequency waves.

The instructions may specify one or more of: a time period during which the at least one light source should be on; a time period during which the at least one light source should be off; an intensity of light to be emitted from the at least one light source; and a wavelength of light to be emitted from the at least one light source. The instructions may also specify a polarisation of the light emitted from the device. The polarisation may be augmented or altered by application of a controllable polarising filter in the device.

The power source may be configured to provide power to the at least one light source only when the light emitting device is submerged in seawater. Automatically turning the at least one light source on and off in response to the light emitting device being submerged in and removed from seawater respectively further simplifies interaction of a user with the device. The light emitting device may not be accidentally turned on or off when unintended. Life of the power source may also be saved or extended by not needlessly powering the at least one light source when not required.

The light emitting device may further comprise a capacitive sensor enclosed within the first housing portion. The power source may be configured to provide power to the at least one light source only when a capacitive measurement obtained by the capacitive sensor indicates that the light emitting device is submerged in seawater.

Typically, devices which automatically turn on and off on submersion in or removal from seawater utilise probes extending externally from the device to measure resistivity of the surrounding medium (and complete an electric circuit using ions present in seawater). Probes extending through a housing of a device act as local stress concentrators at the point at which they extend through the housing and make the housing more susceptible to failure. Probes also increase the complexity of the mechanical design of a housing for a device.

By utilising a capacitive sensor fully enclosed within the first housing portion to measure the dielectric properties of a medium surrounding the device, no water sensing probes are required to extend through the first housing portion. Local stress concentrators are therefore removed from the housing design. As the dielectric properties of air and water are sufficiently different, the light emitting device may determine when it is submerged in seawater. In this way, a “contactless” water sensing mechanism may be provided. Galvanic corrosion of probes extended from the housing may therefore be avoided, further reducing user maintenance requirements for the light emitting device.

A further benefit of capacitive sensing of the dielectric properties of a medium surrounding the light emitting device may be that salinity of seawater (which is strongly correlated with the dielectric properties of water) or other oceanographic data (e.g., water temperature, oxygen concentration, carbon dioxide concentration, water depth, ambient light levels) may be measured and recorded. For example, measurements of seawater salinity and other oceanographic data may be made by the capacitive sensor and stored in the memory. The stored measurements may be transmitted to a user device when instructed by a user.

The device may comprise one or more additional sensors configured to measure one or more other parameters relating to oceanographic data such as water temperature, water depth, oxygen concentration, ambient light levels, water turbidity and carbon dioxide concentration. The device may comprise additional sensors to capture information relating to the usage of the device. For example, one or more of a submersion time, submersion duration and submersion location could be recorded by the device. This information could be correlated with oceanographic data to reveal any relationships in the data.

The light emitting device may be configured to be attachable or attached to a fishing device. The light emitting device may further comprise an attachment or fastener such as a sprung clip configured to attach the light emitting device to a fishing device. The sprung clip may be removably attachable or attached to the light emitting device. An advantage of a sprung clip is that the light emitting device may be attached to a fishing device without the use of tools or disposable fixings which may contribute to pollution of rivers and oceans. A removably attached sprung clip may enable a sprung clip of a different shape to be attached to light emitting device. Sprung clips of different shapes may enable the light emitting device to be easily, efficiently and securely attached to a wide variety of different fishing devices (for example, thick rope, fishing net of different gauges, steel wire, solid beams or material in fishing pots).

The light emitting device may be configured to selectively emit light in at least one of a first direction; and a second direction antiparallel to the first direction. Customisability of the emission of light from the at least one light source for different subsea scenarios may enable a more effective lure for selectively catching adult fish or other ocean organisms rather than juvenile fish or other ocean organisms. Furthermore, it may desirable for the at least one light source to illuminate certain regions of the underwater environment, but not other. For example, if the light emitting device is attached to a fishing device (e.g., a net), a user may wish to illuminate one side of the fishing device, but not the other side. In other situations, a user may wish to use the light emitting device as a “point source” of light, wherein the light emitting device may emit light in both the first and second directions simultaneously. The at least one light source may be or comprise at least one light emitting diode.

The second housing portion may be configured to prevent ingress of water at depths of up to 1000 m.

According to a second aspect of the invention, there is provided a system comprising a plurality of light emitting devices according to first aspect of the invention. The plurality of light emitting devices may be configured to emit light cooperatively. The plurality of light emitting devices may be configured to emit light cooperatively to produce at least one of a temporal pattern, a spatial pattern and a colour pattern. The plurality of light emitting devices may be configured such that the outputs of each of the light emitting devices are coordinated to produce one or more distributed temporal, spatial or colour-based light patterns. Utilising a plurality of light emitting devices to produce a light display may provide a more effective lure for selectively catching adult fish rather than juvenile fish than using a single light emitting device. A plurality of light emitting devices may be able to cover a larger region of an underwater environment than achievable using a single light emitting device. Different light displays may also be used to specifically target particular species of fish or other ocean organisms.

The system may further comprise a user device. The user device may comprise a user interface configured to enable a user to select instructions to control each of the plurality of light emitting devices. The user device may be configured to communicate instructions to each of the plurality of light emitting devices via wired or wireless communication. The user device may be configured to communicate instructions to each of the plurality of light emitting devices via infrared communication. The system may further be useable with or comprise a USB dongle connectable to the user device. The USB dongle may be configured to communicate instructions to each of the plurality of light emitting devices via infrared communication.

Marine and subsea environments are typically harsh environments for radio frequency communications, as, for example, strong electromagnetic waves may be emitted from nearby radar antenna. Such electromagnetic waves may cause interference with radio frequency communication used to communicate instructions to devices. By instead utilising infrared communication, a more robust medium for communication of instructions in a subsea environment may be achieved, avoiding interference with radio frequency waves.

Furthermore, traditional wireless techniques require a user to “pair” each light emitting device with the user device separately, resulting in a lengthy setup process. By utilising a USB dangle connectable to the user device, infrared communication may be used to simultaneously communicate instructions to each of the plurality of light emitting devices in the optical field of view of the USB dongle.

The instructions may specify one or more of: a time period during which the at least one light source of each of the plurality of light emitting devices should be on; a time period during which the at least one light source of each of the plurality of light emitting devices should be off; an intensity of light to be emitted from the at least one light source of each of the plurality of light emitting devices; and a wavelength of light to be emitted from the at least one light source of each of the plurality of light emitting devices. The instructions may also specify a polarisation of light emitted from each of the plurality of light emitting devices. The polarisation may be augmented or altered by application of a controllable polarising filter in the device.

The system may comprise a wireless charging module. The wireless charging module may be configured to wirelessly charge at least a subset of the plurality of light emitting devices simultaneously. A wireless charging module enabling at least a subset of the plurality of light emitting devices to be wirelessly charged simultaneously may simplify interaction of a user with the plurality of light emitting devices and also with the system. The user may not be required to replace batteries in each of the plurality of light emitting devices separately, which may reduce time spent by the user charging the plurality of light emitting devices.

A simplified charging process may encourage more frequent charging of the plurality of light emitting devices. More frequent charging of the plurality of light emitting devices may extend a lifetime of the wirelessly chargeable power source of each of the plurality of light emitting devices, as fewer deep-discharge cycles may be incurred. Furthermore, battery waste from disposable batteries is significantly reduced.

The wireless charging module may comprise a plurality of recesses, each of the plurality of recesses configured to receive at least one of the plurality of light emitting devices during wireless charging of at least a subset of the plurality of light emitting devices.

### BRIEF DESCRIPTION OF THE DRAWINGS

The invention will now be described by way of example with reference to the accompanying drawings in which:

FIG. 1 shows an isometric view of a light emitting device;

FIGS. 2A and 2B show cross-sectional views of the light emitting device of FIG. 1;

FIG. 3 shows an exploded assembly view of the light emitting device of FIG. 1;

FIG. 4 a printed circuit board for use in a light emitting device e.g. of the type shown in FIG. 1;

FIG. 5 shows a schematic of electrical and electronic components in a light emitting device e.g. of the type shown in FIG. 1;

FIG. 6 shows a functional schematic of a light emitting device e.g. of the type shown in FIG. 1;

FIG. 7 shows a flowchart illustrating the operation of a light emitting device e.g. of the type shown in FIG. 1;

FIGS. 8A and 8B respectively show a user device for controlling one or more light emitting devices e.g. of the type shown in FIG. 1, and a system comprising a user device and a plurality of light emitting devices e.g. of the type shown in FIG. 1;

FIG. 9 shows a light emitting device according to another embodiment with selective directional light emission:

FIG. 10 shows a location of a capacitive sensor in a light emitting device e.g. of the type shown in FIG. 1 or 9;

FIGS. 11A to 11H show a light emitting device e.g. of the type shown in FIG. 1 or 9 comprising a sprung clip;

FIGS. 12A and 12B show different embodiments of a sprung clip for a light emitting device e.g. of the type shown in FIG. 1 or 9;

FIGS. 13A and 13B show a wireless charging module for wirelessly charging one or more light emitting devices e.g. of the type shown in FIG. 1 or 9.

Features which are described in the context of separate aspects and embodiments of the invention may be used together and/or be interchangeable wherever possible. Similarly, where features are, for brevity, described in the context of a single embodiment, these may also be provided separately or in any suitable sub-combination. Features described in connection with the light emitting device may have corresponding features definable with respect to the system and/or to methods of use, operation or manufacture, and these embodiments are specifically envisaged.

### DETAILED DESCRIPTION

As used herein, the term “fishing device” encompasses any apparatus for use in catching fish. Specific fishing devices may include nets, such as trawl nets and purse-seines, and fishing pots. The term “light” is used in the sense that it is used in optical systems, to mean not just visible light, but also electromagnetic radiation having a wavelength outside that of the visible range.

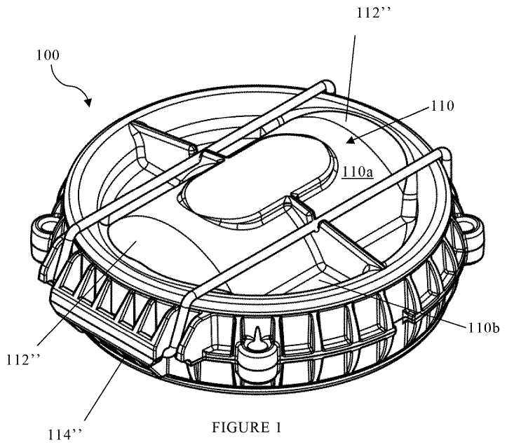

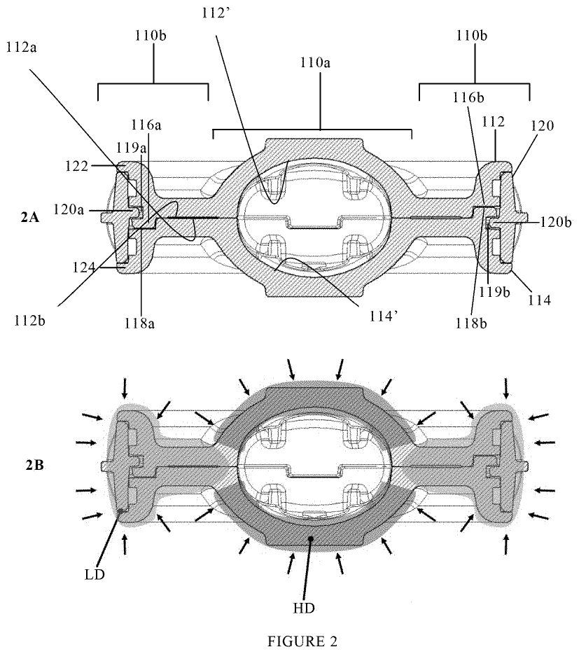

FIGS. 1 and 2 show an embodiment of a light emitting device 100 for a subsea environment. In the embodiment shown, the light emitting device comprises at least one light source (not shown), a wirelessly chargeable power source (not shown), and a housing 110. The light emitting device 100 has a substantially plate-like shape. The light emitting device 100 may be considered to have a low aspect ratio cylindrical shape. In other embodiments, the light emitting device 100 may have any suitable shape, for example a sphere, a cylinder, or a torus.

The housing 110 (shown in hatching) comprises a first housing portion 110a and a second housing portion 110b. The at least one light source and the wirelessly chargeable power source are enclosed within a cavity defined by the first housing portion 110a. The second housing portion 110b provides or comprises a fluid-tight seal for the housing 110. Both the first housing portion 110a and the second housing portion 110b are configured to allow transmission of light emitted by the at least one light source to the subsea environment (i.e., the first housing portion 110a and the second housing portion 110b are fully or partially transparent or translucent, or comprise areas which are fully or partially transparent or translucent).

In enclosing the at least one light source and the wirelessly chargeable power source, the first housing portion 110a is configured to act as a pressure vessel.

In the embodiment shown in FIG. 2A, the housing 110 comprises an upper half 112 and a lower half 114. It should be noted that the terms “upper half” and “lower half” are for ease of description in relation to the view of the device 200 in FIG. 2A only. In use, the device may be positioned or rotated at an angle such that at least a part of the upper half 112 is below at least a part of the lower half 114 (i.e., submerged deeper than the lower half 114),

The upper half 112 of the housing 110 comprises a recessed portion 112′ which is configured to, in combination with a recessed portion 114′ of the lower half 114, form the first housing portion 110a when the upper half 112 and the lower half 114 are attached to one another. Each of the recessed portions 112′, 114′ comprises a substantially half cylindrical shape with a hemispherical end portion 112″, 114″ at each end, the recessed portions together forming a first housing portion 110a in the shape of a cylinder with hemispheric ends when the upper half 112 and the lower half 114 are attached. In other embodiments, each of the upper half and lower half may be substantially hemispherical in shape, forming a first housing portion comprising a substantially spherical cavity when the upper half and the lower half are attached.

The upper half 112 of the housing 110 also comprises a contacting surface 112a which is configured to mate with a contacting surface 112b of the lower half 114 to form at least a part of the second housing portion 110b. To aid location of the upper half 112 onto the lower half 114, the contacting surface of the upper half 112 comprises a lip 116a which forms an arc extending about the axial direction of the cylindrically shaped device 100. The lip 116a may be located at any suitable radial position in the second housing portion 110b. In the embodiment shown, the lip 116a is located substantially at the circumference of the upper half 112. A corresponding recess 118a is formed in the contacting surface of the lower half 114. In the embodiment shown, the lip 116a and corresponding recess 118a are located circumferentially on the contacting surfaces of upper half 112 and the lower half 114 respectively. In the embodiment shown, the arcs of the lip 116a and the corresponding recess 118a extend approximately one half of the circumference of the upper half 112 and the lower half 114 respectively. A recess 116b in the contacting surface of the upper half 112 and a corresponding lip 118b formed in the contacting surface of the lower half 114 are formed in substantially the same manner as the lip 116a and the corresponding recess 118a. The arcs of the recess 116b and the corresponding lip 118b extend substantially the remainder of the circumference of the upper half 112 and the lower half 114 respectively. It will be appreciated that the lip 116a, 116b/recess 118a, 118b could be in the lower half 114/upper half 112 instead of in the upper half 112/lower half 114.

The upper half 112 and the lower half 114 are further held together by a closure ring 120. A first protrusion 120a extending from an inner surface of the closure ring 120 engages a corresponding recess 119a on an outer surface of the upper half 112 of the housing 110. A second protrusion 120b from an inner surface of the closure ring 120 engages a corresponding recess 119b on an outer surface of the lower half 114 of the housing. The engagement of the first protrusion 120a and second protrusion 120b of the closure ring 120 with the corresponding recesses 119a, 119b on outer surfaces of the upper half 112 and of the lower half 114 respectively acts to prevent separation of the upper half 112 from the lower half 114 of the housing 110 While the closure ring 120 is in place. The closure ring 120 is further held between a protrusion 122 extending radially from the upper half 112 around a circumference of the upper half 112, and a protrusion 124 extending radially from the lower half 114 around a circumference of the lower half 114.

The fluid-tight seal of the housing 110 is provided by one or more O-ring seals (not shown). The O-ring seal seals may be located between outer surfaces of the upper half 112 and the lower half 114 of the housing 110 and an inner surface of the closure ring 120. The O-ring seals are located in recesses formed in outer surfaces of the upper half 112 and the lower half 114. In other embodiments, the O-ring seals may be located in corresponding recesses formed in an inner surface of the closure ring 120.

The closure ring 120 may be removed should the upper half 112 and the lower half 114 of the housing require separation to access any of the components enclosed within the first housing portion 110a.

In alternative embodiments, the housing may be formed from a single piece of material. The single piece of material may be shaped around the electronic components (e.g., the at least one light source and the wirelessly chargeable power source) to enclose the electronic components, forming a first housing portion. The single piece of material may then be formed (e.g., by welding, adhesives etc.) to provide a second housing portion radially displaced from and surrounding the first housing portion, the second housing portion forming a fluid-tight seal.

The first housing portion 110a enclosing the at least one light source and the wirelessly chargeable power source results in the first housing portion 110a acting as a pressure vessel, independently of the second housing portion 110b comprising the fluid-tight seal to prevent fluid ingress into the light emitting device 100.

By forming the housing 110 with distinct portions 110a, 110b which perform separate roles (i.e., the first housing portion 110a acting as a pressure vessel, and the second housing portion 110b acting to seal the housing), the sealing surface of the housing 110 is separated from the part of the device 100 configured to act as a pressure vessel. As a result, deformations in the pressure vessel or first housing portion 110a of the housing 100 when the device 100 is subjected to pressure (e.g., pressure in a subsea environment) do not compromise the integrity of the fluid-tight seal of the sealing surface or second housing portion 110b.

Since deformations in the first housing portion 110a do not compromise the integrity of the fluid-tight seal of the second housing portion 110b, the first housing portion 110a need not be made as rigid (and therefore as large and heavy) as typical pressure vessels designed for similar subsea environments. The first housing portion 110a may therefore comprise thinner walls than typically required for pressure vessels designed for similar subsea environments, such that the walls of the first housing portion can deform to a greater extent than normally allowable. This effect is shown in FIG. 2B, where the area labelled HD indicates where deformation or deflection of the device 100 is concentrated when pressurised in the subsea environment (i.e., an area of high deformation. The area labelled LD indicates where low deformation of the device 100 takes place, even when pressurised in the subsea environment (i.e., an area of low deformation). The arrows indicate pressure due to the surrounding water in a subsea environment.

This housing 110 design allows for a smaller central cavity within the first housing portion 110a. The first housing portion 110a may be surrounded by material forming the second housing portion 110b which is not required to structurally support or react to any pressurising loads in subsea environments, but is instead designed with the intention of solely sealing the housing 110. This may enable the light emitting device to be use less structural material and therefore have a lower mass than typical pressure vessels designed for similar subsea environments.

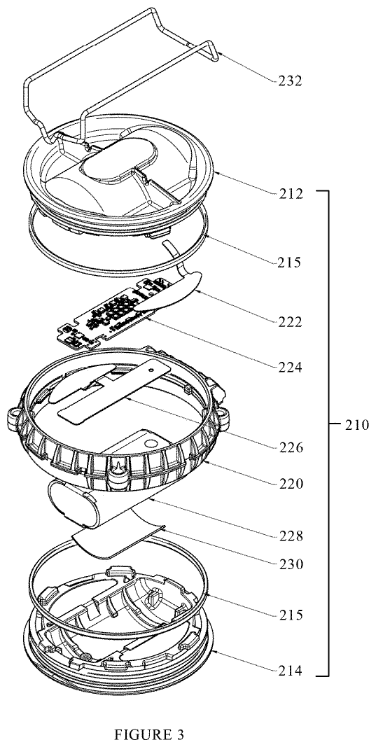

FIG. 3 shows an exploded assembly view of an embodiment of a light emitting device 200. The device 200 comprises a housing 210. The housing 210 is substantially as described above with respect to FIGS. 1 and 2. The housing comprises an upper half 212 and a lower half 214 which together form a first housing portion and a second housing portion as described above. The device also comprises a closure ring 220 configured to hold the upper half 212 and the lower half 214 of the housing 210 together, as described previously. The device further comprises O-ring seals 215 configured to form a fluid-tight seal in the housing 210. The device 200 further comprises a capacitive sensor 222, a printed circuit board (PCB) 224, a heat sink 226, a rechargeable battery 228, and a wireless charging coil 230. The device 200 also comprises a clip 232 for attaching the device 200 to a fishing device.

Capacitive sensor 222 is configured to measure the dielectric properties of a medium surrounding the light emitting device 200 in order to determine whether the device 200 is submerged in seawater or not. In this way, the device 200 may determine whether or not the device 200 is submerged in seawater without requiring an external probe extending from the device 200 to be in physical contact with the medium surrounding the device 200.

The capacitive sensor 222 is further configured to provide capacitive measurement data to a microcontroller located on the PCB 224 to determine whether or not the device 200 is submerged in seawater. The capacitive measurement data may be stored in a memory of the microcontroller. In this way, the device 200 can also be configured to store, for example, measurement data on the salinity of the seawater, and/or other oceanographic data (e.g., water temperature, water depth, oxygen concentration, carbon dioxide concentration, water flow rate, water flow direction, chlorophyll concentration, presence of other chemicals in water). Alternatively, the device may comprise one or more additional sensors each configured to measure one or more other parameters relating to oceanographic data such as water temperature, water depth, oxygen concentration, carbon dioxide concentration, water flow rate, water flow direction, water turbidity, chlorophyll concentration, and a presence of other selected chemicals in the water).

The wireless charging coil 230 is configured to receive wirelessly transmitted power from a wireless charging module (not shown) in order to provide power to the rechargeable battery 228. The heat sink 226 is configured to dissipate heat from the various electronic and electrical components contained within the housing 210.

The clip 232 is configured to provide an easy and simple attachment mechanism in order to attach the light emitting device 200 to a fishing device, for example, a net or a fishing pot.

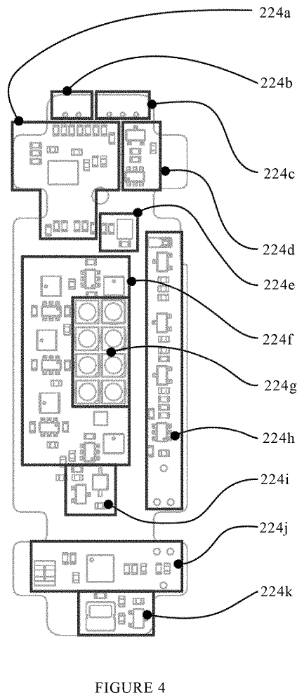

FIG. 4 shows a view of the PCB 224 of the device 200. The PCB comprises a wireless charging circuit 224a and a wireless charging coil connector 224b. The charging coil connector 224b is connected to the wireless charging coil 230. The wireless charging circuit 224a transmits power received by the wireless charging coil 230 to the rechargeable battery 228 via a battery connector 224c. In alternative embodiments, the device may comprise a wired connection for charging the device, in addition to or instead of wireless charging capabilities.

The PCB 224 further comprises a battery protection circuit 224d configured to protect the rechargeable battery 228 from sustaining damage whilst either charging using power received wirelessly by the wireless charging coil 230, or providing power (i.e., discharging) to other electronic components located on the PCB 224. A power conditioning circuit 224e is configured to regulate power distribution to the rechargeable battery 228. The PCB 224 may also comprise one or more voltage regulation circuits to provide a stable voltage to one or more electronic or electrical components located on the PCB 224.

The PCB 224 also comprises LED drivers 224f, and an array of LEDs 224g. The at least one light source of the light emitting device 200 comprises the array of LEDs 224g. The LED drivers 224f are configured to regulate the power provided to each of the LEDs in the array of LEDs 224g. The PCB 224 further comprises an LED user indicator circuit 224i to provide feedback to a user of the device 200 via one or more LEDs of the array of LEDs 224g. In alternative embodiments, the at least one light source of the device 200 may be any suitable source of light, for example one or more filament light bulbs or lasers.

A capacitive sensing circuit 224h is configured to provide power to the capacitive sensor 222 and to monitor and transmit the capacitive measurements obtained by capacitive sensor 222. The capacitive sensor 222 comprises a patch of conductive material which forms a first half of a capacitive system. A second half of the capacitive system is made up of the material surrounding the device (e.g., seawater) such that the capacitance of the system varies depending on the surrounding material. The capacitive sensing circuit 224h excites the capacitive sensor 222 (i.e., excites the conductive material patch) and measures the frequency response of the capacitive system. From the frequency response, a capacitance value can be derived and correlated against known values of materials (e.g., seawater). The capacitive sensor 222 can be connected to the PCB 224 using a sprung contact pin, a physical connection or can be integrated into the PCB.

The PCB 224 further comprises a microcontroller 224j, and a joint ambient light sensor and IR receiver 224k. In alternative embodiments, an ambient light sensor and an IR receiver may be provided as separate components on the PCB. In other embodiments, the device may comprise a receiver configured to receive information via other forms of wireless communication than IR, for example via Bluetooth® or WiFi®, or a (general) RF transmitter. The device may also comprise a transmitter configured to transmit information via IR or other forms of wireless communication. The device may be configured to send and/or receive information via other forms of wireless communication instead of or in addition to IR.

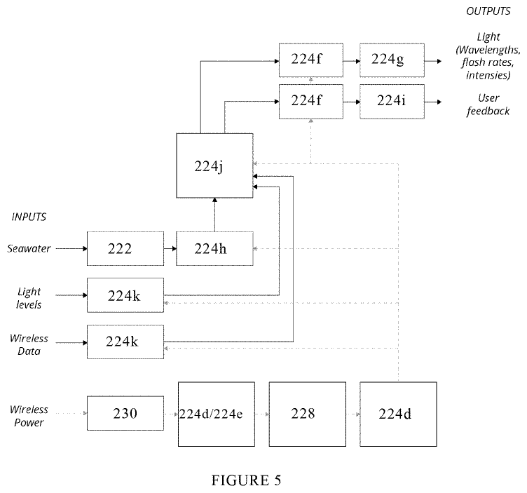

FIG. 5 shows a schematic diagram of the layout of the electronic components of light emitting device 200. FIG. 5 also illustrates how inputs into the device 200 are converted into outputs from the device 200. Wireless power is received by the wireless charging coil 230 and directed to the rechargeable battery 228. The battery protection circuit 224d monitors both the charging and discharging of the rechargeable battery 228 to ensure the rechargeable battery 228 is protected. The power conditioning circuit 224e regulates power distribution from the rechargeable battery 228 to the joint ambient light sensor and IR receiver 224k, and the capacitive sensor 222. Voltage regulation of power provided from the rechargeable battery 228 to those components, the microcontroller 224j and the LED drivers 224f also takes place.

Wireless data transmitted via infrared communication is received by the joint ambient light sensor and IR receiver 224k. The joint ambient light sensor and IR receiver 224k is also configured to monitor ambient light levels. In addition to capacitive measurements obtained by the capacitive sensor 222, ambient light levels detected by the joint ambient light sensor and IR receiver 224k can be used to aid in determining whether or not the light emitting device 200 is submerged in seawater. Data received and/or detected by the joint ambient light sensor and IR receiver 224k is transmitted to the microcontroller 224j. In alternative embodiments, the device may receive data via other forms of wireless communication, and/or may receive data via wired communication. For example, the device may be configured to receive data via USB connection.

The capacitive sensor 222 is configured to obtain measurements of dielectric properties of a medium surrounding the light emitting device 200. The measurements obtained by the capacitive sensor are transmitted to the microcontroller 224j via the capacitive sensing circuit 224h, which is configured to indicate to the microcontroller 224j whether or not the device 200 is submerged in seawater.

After receiving data from at least one of the capacitive sensing circuit 224h and the joint ambient light sensor and IR receiver 224k, the microcontroller 224j provides instructions to the array of LEDs 224g via the LED drivers 224f to control the emission of light from the array of LEDs 224g. The instructions are stored in a memory of the microcontroller 224j. The instructions may be altered, updated or reprogrammed by data received via infrared communication by the joint ambient light sensor and IR receiver 224k.

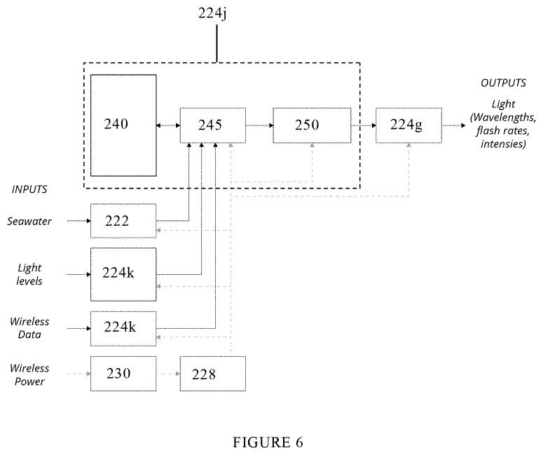

FIG. 6 shows a functional block diagram of showing how various components of the device 200 interact to enable the device 200 to emit light in a controlled manner. The wireless charging coil 230 receives electrical power wirelessly and transmits the received power to the rechargeable battery 228. The rechargeable battery 228 provides power to all other components located on the PCB 224.

The microcontroller 224j comprises a memory 240, a processor 245 and a light source controller 250. Signals from both the capacitive sensor 222, and the joint ambient light sensor and IR receiver 224k are transmitted to the processor 245 of the microcontroller 224j. The processor 245 communicates with both the memory 240 and the light source controller 250 of the microcontroller 224j. The memory 240 stores the instructions for the processor 245 to operate the light source controller 250 in response to signals from at least one of the capacitive sensor 222 and the joint ambient light sensor and IR receiver 224k.

The instructions enable the processor 245 to operate the light source controller 250 to control the emission of light from the array of LEDs 224g. For example, the instructions may be used to control which wavelengths of light are emitted from the array of LEDs 224g, the intensity of light emitted from the array of LEDs 224g, and/or the duration of light emission from the array of LEDs 224g. Controlling the duration of light emission from the array of LEDs enables, for example, flashing displays to be output from the array of LEDs 224g.

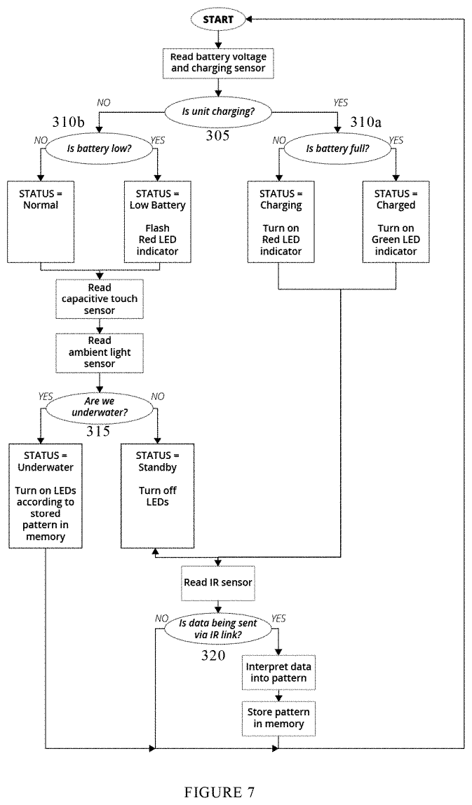

FIG. 7 shows a flowchart depicting how the device 200 operates according to a process 300. At step 305, the processor 245 determines whether or not the rechargeable battery is being charged. If, at step 305, the processor 245 determines that the rechargeable battery 228 is being charged, the processor 245 is further configured to determine whether or not the rechargeable battery 228 is fully charged at step 310a. If the processor 245 determines that the rechargeable battery 228 is fully charged at step 310a, the processor 245 instructs the LED user indicator circuit 224i (via the light source controller 250) to turn on a green LED to indicate the charge status of the rechargeable battery 228 to a user. If the processor 245 instead determines that the rechargeable battery 228 is not fully charged at step 310a, the processor 245 instructs the LED user indicator circuit 224i (via the light source controller 250) to turn on a red LED to indicate the charge status of the rechargeable battery 228 to a user. After step 310a, the processor 245 proceeds to step 320.

If, at step 305, the processor determines that the rechargeable battery 228 is not being charged, the processor 245 is further configured to determine whether or not the rechargeable battery 228 has a low level of charge remaining at step 310b. If the processor 245 determines that the rechargeable battery 228 has a low level of charge remaining at step 310b, the processor 245 instructs the LED user indicator circuit 224i (via the light source controller 250) to flash a red LED to indicate that the level of charge remaining in the rechargeable battery 228 is low. If the processor 245 instead determines that the rechargeable battery 228 does not have a low of charge remaining at step 310b, the processor 245 instructs the LED user indicator circuit 224i (via the light source controller 250) to not turn on any of the LEDs in the array of LEDS 224g. After step 310b, the processor 245 proceeds to step 315.

At step 315, the processor 245 determines whether or not the device 200 is submerged in seawater. Signals from both the capacitive sensor 222 and the joint ambient light sensor and IR receiver are transmitted to the processor 245 to enable the processor 245 determine whether or not the device 200 is submerged in seawater. If the processor 245 determines that the device 200 is submerged in seawater at step 315, the processor 245 instructs the light source controller 250 to turn on one or more LEDs from the array of LEDs 224g according to instructions (e.g., a spatial or temporal pattern) stored in the memory 240. If the processor 245 instead determines that the device 200 is not submerged in seawater at step 315, the processor 245 instructs the light source controller 250 to prevent emission of light from any of the LEDs of the array of LEDs 224g, in order to preserve the charge in the rechargeable battery 228 whilst the device 200 is not underwater.

At step 320, the processor 245 determines whether or not data is being wirelessly transmitted to the device 200 via infrared communication to the joint ambient light sensor and IR receiver 224k of the device 200. If the processor 245 determines that no data is being sent via infrared communication to the device 200 at step 320, the processor 245 returns to step 305 of the process 300. If the processor 245 instead determines that data is being sent via infrared communication to the device 200 at step 320, the processor 245 interprets the received data as a spatial and/or temporal pattern for the emission of light from the array of LEDs 224g. Once the processor 245 has interpreted the received data, the processor 245 communicates with the memory 240 to store the spatial and/or temporal pattern for the emission of light from the array of LEDs in the memory. The processor 245 then returns to step 305 of the process 300.

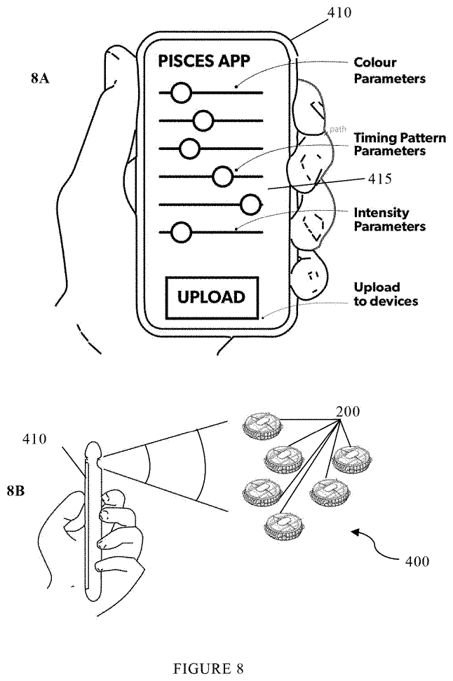

FIG. 8 shows an embodiment of a system 400 comprising a plurality of light emitting devices 200. In the embodiment shown in FIG. 8B, a user device 410 (e.g., a smartphone or tablet) is used to wirelessly communicate with each of the plurality of light emitting devices 200 via infrared communication. In other embodiments, other forms of wireless communication may be utilised instead. Instructions relating to the emission of light from the array of LEDs is transmitted to each of the plurality of devices 200 from the user device 410. In the embodiment shown, a USB dongle configured to transmit information via infrared communication is connected to the user device 410 to enable infrared communication. In other embodiments, a user device may be configured to directly transmit information via infrared communication.

The user device 410 comprises a user interface 415, as shown in FIG. 8A. In the embodiment shown, the user interface 415 comprises a touch screen interface, wherein a number of parameters including (but not limited to) colour of light emission, intensity of light emission and timing pattern of light emission can be altered by the user via the user interface 415. The user can then instruct the user device 410, using the user interface 415, to transmit the parameters as instructions to each of the plurality of devices 200. Once transmitted, the instructions are then stored in the memory 240 of each of the devices 200. In alternative embodiments, the user device may comprise a display screen and one or more buttons to enable the user to control parameters of light emission from each of the plurality of light emitting devices. In other embodiments, the user device may comprise a computer, wherein software (i.e., a computer program) installed on the computer may allow the user to control parameters relation to light emission from each of the plurality of light emitting devices.

The user device 410 is configured to transmit information or data via infrared communication to any of the light emitting devices 200 which are in the optical field of view of the USB dongle (i.e., the infrared source). Each of the plurality of devices 200 in the optical field of view is updated identically with the same control parameters from the user device 410. In other embodiments, each of the plurality of devices may be updated with instructions relating only to light emission from that particular device.

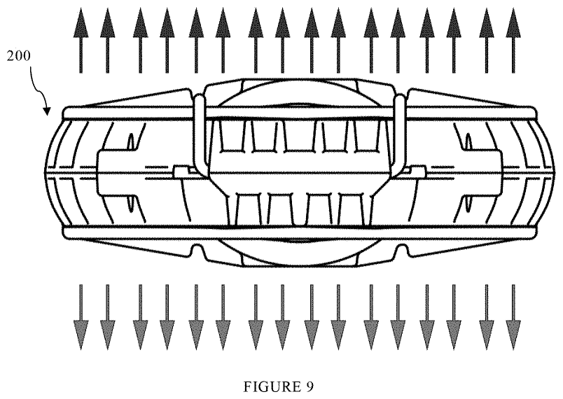

FIG. 9 shows a view of a light emitting device 200. The device 200 is configured to selectively emit light through the first housing portion and the second housing portion, in both the upper half 212 and the lower half 214 of the housing 210. In the embodiment shown, light is transmitted through the upper half 212 in a direction that is antiparallel to the direction of light transmitted through the lower half 214. The device 200 is configured such that light may be selectively emitted through either or both of the upper half 212 and the lower half 214. At least a subset of the array of LEDs 224g is positioned to emit light through the upper half 212, and at least a subset of the array of LEDs 224g is positioned to emit light through the lower half 214. Instructions stored in the memory 240 of the device 200 can be altered to result in emission of light through either or both of the upper half 212 and the lower half 214. The plate-like design of the device 200 (i.e., the device 200 having a low aspect ratio cylindrical shape) enables this feature. In other embodiments, the device may be configured (i.e., via a shape of the housing, or positioning of the at least one light source) to enable, via instructions stored in the memory, selective light emission in a plurality of directions, wherein the plurality of directions may be at any angle with respect to one another.

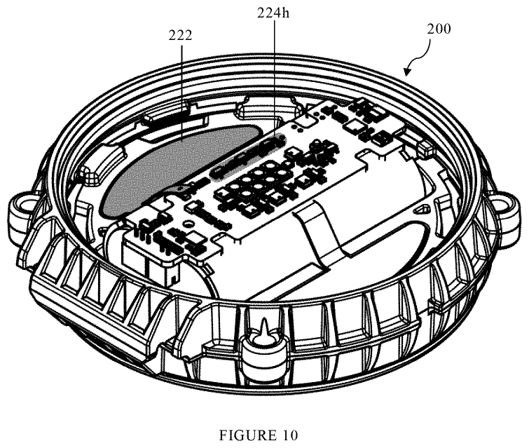

FIG. 10 shows a location of the capacitive sensor 222 and the capacitive sensing circuit 224h in the device 200. The capacitive sensor 222 and the capacitive sensing circuit 224h are located within the first housing portion 110a, near the walls of the first housing portion. As discussed above, the first housing portion comprises thin walls relative to a typical pressure vessel designed for similar subsea environments. By positioning the capacitive sensor 222 and the capacitive sensing circuit 224h near the walls of the first housing portion, the device 200 is able to utilise the thin walls to improve the ease and efficiency of making capacitive measurements to determine the dielectric properties of a medium surrounding the device 200. In other embodiments, the capacitive sensor and capacitive sensing circuit may be located at any point within the first housing portion, preferably near a wall to maximise ease an efficiency of making capacitive measurements.

The benefits of a housing 210 as described above for the device 200 are numerous. The housing 210 comprising a) a first housing portion defining a cavity and configured to act as a pressure vessel containing all electronic and electrical components of the light emitting device, and b) a second housing portion configured to provide a fluid-tight seal for the housing 210, allows the first housing portion to comprise thin walls. Thin walls in the first housing portion may improve transmission of light emitted by the at least one light source through the housing 210, and allow for efficient wireless charging of the device 200. Heat dissipation from the electronic and electrical components in the first housing portion may also be improved by the first housing portion comprising thin walls. Capacitive sensing by the capacitive sensor 222 and the capacitive sensing circuit 224h may be made easier and more efficient by the thin walls of the first housing portion. Finally, wireless communication via infrared communication may be made more efficient by the thin walls of the first housing portion, with wireless data signals experiencing less attenuation than for thicker housing walls.

User interaction with the device 200 may therefore be greatly simplified by the thin walls of the first housing portion, because no access to the internal space defined by the first housing portion may be required in order for the user to perform maintenance tasks. All transfer of information and power to the device 200 can take place wirelessly through the thin walls of the first housing portion, thereby eliminating the need for wired connections to the device 200. As such, the housing 210 may require no opening mechanism, a hinge mechanism located at a joint between the upper half 212 and the lower half 214. There may therefore be a great reduction in mechanical wear of the housing 210 compared to housings for devices which require opening and closing to access an interior space of the housing.

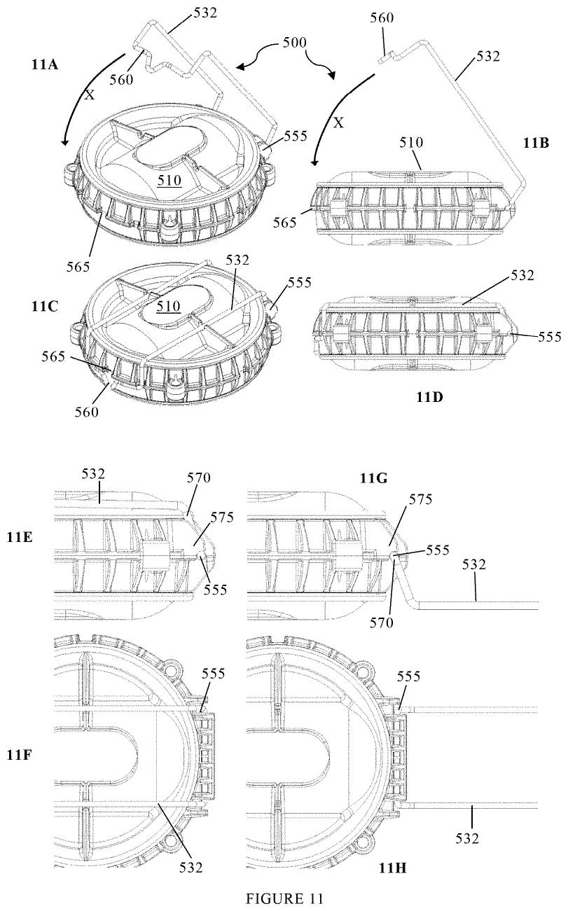

FIGS. 11A to 11H show an embodiment of a light emitting device 500. The device 500 is substantially identical to the embodiments described with respect to FIGS. 1 to 10. The device 500 comprises a sprung clip 532. The sprung clip 532 is attached to a housing 510 of the device 500 via a hinge point 555, about which the sprung clip 532 is configured to rotate. The sprung clip 532 further comprises a locking end 560 configured to engage with a corresponding locking point 565, located on the housing 510 and displaced from the hinge point 555, when the sprung clip 532 is in a closed position. FIGS. 11A to 11D show side views and isometric views of the sprung clip 532 being brought into a closed position (FIGS. 11A and 11B, with arrows X showing a closing direction) and in a closed position (FIGS. 11C and 11D).

In the embodiment shown, the locking end 560 is brought into a closed position by applying force (e.g., by a user) to elastically deform the sprung clip 532 to enable the locking end 560 to move past the locking point 565. Once the locking end 560 has been moved past the locking point 565, the applied force is removed such that the sprung clip 532 reverts to its elastically undeformed state and the locking end 560 engages with the locking point 565. When in its elastically undeformed state and in engagement with the locking point 565, the sprung clip 532 is not able to move past the locking point 565 towards an open position. To release the engagement of the locking end 560 with the locking point 565 and bring the sprung clip 532 to an open position, force must be applied to the locking end 560 to elastically deform the sprung clip 532. When a sufficient elastic deformation occurs, the locking end 560 is able to move past the locking point 565 such that the sprung clip 532 is in an open position (i.e., the locking end 560 is not engaged with the locking point 565). In the embodiment shown, force may be applied to a pull tag (shown in FIGS. 11A and 11C as an arrowhead shape extending from the locking end 560) to elastically deform the sprung clip 532 when moving the sprung clip 532 to both the closed position and the open position.

The hinge point 555 extends a length along the housing 510. The binge point 555 comprises, at each end of the hinge point 555, a hole or channel (not shown) for locating a hinge arm 570 of the sprung clip 532, as shown in FIGS. 11E to 11H. In alternative embodiments, the channels may extend such the channels meet to form a single channel extending the length of the hinge point 555. In the embodiment shown, the hinge arm 570 extends a full width of the sprung clip 532. In alternative embodiments, the sprung clip may comprise a hinge arm which does not extend a full width of the sprung clip, but rather comprise two hinge arms, one extending inwards from either side of the sprung clip, each of which extend a part of the full width of the sprung clip.

The hinge point 555 also comprises, at each end of the hinge point 555, a hinge guard 575. The hinge guards 575 are configured to prevent removal of the sprung clip 532 from the device 500 whilst the sprung clip 532 is in the closed position. In the embodiment shown, the hinge guards 575 extend circumferentially about the holes or channels in which the hinge arm 570 is received, along part of but not the entire circumference of the channels.

The part of the circumference of the channels about which the hinge guards 575 extend is such that when the sprung clip 532 is in the closed position (or rotated about the hinge point 555 to a position that is substantially similar to the closed position), the hinge guards 575 prevent translational movement of the sprung clip 532 relative to the hinge point 555 that would allow removal of the hinge arm 570 from the channel. When the sprung clip 532 is in or near to the closed position, the hinge arm 570 may therefore only move via rotation about the hinge point 555. However, when in or near to the open position, the sprung clip 532 is not prevented by the hinge guards 575 from translational movement relative to the hinge point 555. In this way, the sprung clip 532 is easily removed from the device 500 when in or near to the open position. This is illustrated further in FIGS. 11E to 11H, which show side and plan views of the sprung clip 532 in both the fully closed (FIGS. 11E and 11F) and the fully open (FIGS. 11G and 11H) positions.

In alternative embodiments comprising two hinge arms as described above, the sprung clip may be removed from the holes or channels at the hinge point by elastically deforming the sprung clip to an extent where the hinge arms are no longer located in the holes or channels at the hinge point (i.e., the lateral distance between the hinge arms is increased during elastic deformation so that the distance is greater than the lateral distance between the channels at either end of the hinge point). In such embodiments, hinge guards may not be required. In other embodiments, the sprung clip may extend from the hinge point to the locking point (in the closed position) around the circumference of the housing, rather than across a diameter of the housing as in the embodiments shown in FIG. 11.

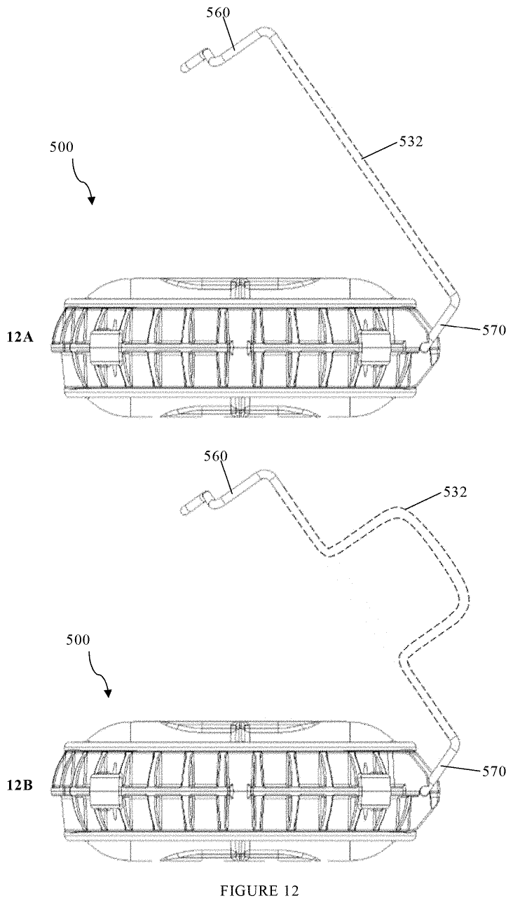

FIG. 12 shows two embodiments of a device 500 comprising a sprung clip 532 as discussed with respect to FIG. 11. The embodiment shown in FIG. 12A shows a sprung clip 532 comprising a straight profile (shown in dashed lines) extending from the hinge arm 570 to the locking end 560. The embodiment shown in FIG. 12B shows a sprung clip 532 comprising a shaped profile (shown in dashed lines) extending from the hinge arm 570 to the locking end 560. The shaped profile shown in FIG. 12B is substantially U-shaped, to allow the device 500 to be easily attached to a larger attachment point of a fishing device (for example, a handle of a fishing pot, rather than the twine of a fishing net) by utilising the U-shaped profile. In alternative embodiments, the sprung clip may comprise a profile of any suitable shape extending between the hinge arm 570 and the locking end 560. For example, the sprung clip may comprise a shaped profile in the form of a plurality of V-shaped protrusions (i.e., representing a multiple saw-tooth shape profile). A plurality of interchangeable sprung clips (which may be attached and removed from the device as described with respect to FIG. 11) with different shaped profiles may be provided to enable efficient and easy attachment of the device to a wide variety of fishing devices.

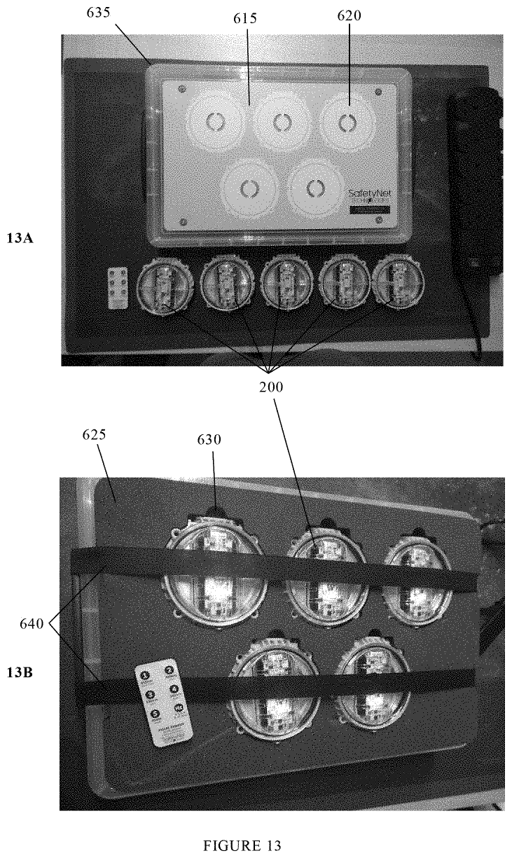

FIG. 13 shows an embodiment of a system 600 comprising a wireless charging module 610 and a plurality of light emitting devices 200. The wireless charging module 610 comprises a charging plate 615 with a plurality of charging points 620, and a locating layer 625 comprising a plurality of recesses or apertures 630 corresponding to the plurality of charging points 620. The locating layer 625 is configured to be placed on the charging plate 615 such that the plurality of charging points 620 and the plurality of recesses or apertures 630 are aligned. The wireless charging module 610 also comprises a storage box 635 within which the charging plate 615, locating layer 625 and devices 200 may be kept during storage or transit. The storage box 635 comprises a chamber and a lid which, when attached together, form an enclosed space in which the charging plate 615, locating layer 625 and devices 200 may be stored or transported. The locating layer 625 comprises a foam material to protect the devices 200 from damage during storage or transit. In alternative embodiments, the wireless charging module may not comprise a locating layer.

FIG. 13A shows the wireless charging module 610 without a locating layer, and with no light emitting devices 200 located on any of the charging points 620 of the charging plate 615. FIG. 13B shows the wireless charging module 610 with a plurality of light emitting devices 200, each of the plurality of devices 200 located in a recess or aperture 630 of the locating layer 625. The recesses or apertures 630 of the locating layer 625 are aligned with the charging points 620 of the charging plate 615 such that each device 200 is aligned with a charging point 620. In the embodiment shown, a pair of straps 640 is provided with the wireless charging module 610 to retain the devices 200 in the plurality of recesses 620 during wireless charging. The straps 640 may also be used to retain the devices 200 in the plurality of recesses 620 during storage or transit. In alternative embodiments, the wireless charging module may not comprise straps.

By locating a light emitting device 200 in each of the recesses 630 of the locating layer 625 or on each of the charging points 620 of the charging plate 615, the user may be able to easily track the location of each of the plurality of light emitting devices 200 whilst the devices 200 are not in a subsea environment (i.e., not in use). Furthermore, by locating each of a plurality of light emitting devices 200 either in a recess 630 of the locating layer 625, or directly on a charging point 620 of the charging plate 615 of the wireless charging module 610, the plurality of devices 200 may be located within a compact area (i.e., an area having a footprint no larger than the size of the wireless charging module 610). In this way, each of the plurality of devices 200 may be easily updated using data transmitted via infrared communication whilst located on the wireless charging module 610. As such, the user may not be required to manipulate or move the optical field of view of a user device transmitting data via infrared communication in order to wirelessly communicate with the plurality of devices 200 during wireless charging.

The wireless charging module 610 is configured to wirelessly charge a plurality of light emitting devices 200 by transmitting power wirelessly to the wireless charging coil 230 of each device 200, as discussed above. The wireless charging module 610 is configured to wirelessly charge any of the light emitting devices 200 when the device 200 is located on a charging point 620 of the charging plate 615, or in a recess 630 of the locating layer 625. In alternative embodiments, the wireless charging module 610 may be configured to wirelessly charge a light emitting device 200 when the light emitting device 200 is located with a certain distance from the wireless charging module 610 (for example, within 30 cm of the wireless charging module 610, or within 10 cm of the wireless charging module 610, or within 5 cm of the wireless charging module 610).

The wireless charging module 610 is configured to wirelessly charge a plurality of light emitting devices using the Qi wireless charging protocol. In other embodiments, the wireless charging module may be configured to wireless charge a plurality of light emitting devices according to any wireless charging protocol.

From reading the present disclosure, other variations and modifications will be apparent to the skilled person. Such variations and modifications may involve equivalent and other features which are already known in the art of light emitting devices, and which may be used instead of, or in addition to, features already described herein. Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention. Features which are described in the context of separate embodiments may also be provided in combination in a single embodiment. Conversely, various features which are, for brevity, described in the context of a single embodiment, may also be provided separately or in any suitable sub-combination. The applicant hereby gives notice that new claims may be formulated to such features and/or combinations of such features during the prosecution of the present application or of any further application derived therefrom. Features of the devices and systems described may be incorporated into/used in corresponding methods.

For the sake of completeness, it is also stated that the term “comprising” does not exclude other elements or steps, the term “a” or “an” does not exclude a plurality, a single processor or other unit may fulfil the functions of several means recited in the claims and any reference signs in the claims shall not be construed as limiting the scope of the claims.

1. A light emitting device for a subsea environment, the device comprising:
at least one light source;
a power source; and
a housing, the housing comprising:
a first housing portion, wherein the at least one light source and the power source are enclosed within the first housing portion; and
a second housing comprising a fluid-tight seal for the housing.

2. The light emitting device of claim 1, wherein the housing is formed of two or more housing components configured to mutually engage with each other and, optionally, a seal configured to engage with the first and/or second housing component.

3. The light emitting device of claim 1, wherein the at least one light source is configured to emit light at one or more wavelengths and, optionally or preferably, wherein the at least one light source comprises at least one light emitting diode.

4. The light emitting device of claim 1, wherein the device further comprises a means for selecting one or more output parameters defining emission of light from the device based on one or more input parameters input to the device by a user; or
wherein the device further comprises a means for selecting one or more output parameters defining emission of light from the device based on one or more input parameters input to the device by a user and the input parameter(s) comprise at least one of:
(i) one or more species of ocean organisms to be targeted by the light emitting device; and
(ii) expected fishing conditions.

5. canceled.

6. The light emitting device of claim 1, further comprising:
a light source controller configured to control emission of light from the at least one light source; and
a memory configured to store instructions for controlling the emission of light from the at least one light source;
wherein the light source controller is configured to control the emission of light from the at least one light source based on the stored instructions; and
wherein the light source controller and the memory are enclosed within the first housing portion.

7. The light emitting device of claim 6, wherein the device is configured to receive instructions from a user device via wired or wireless communication and/or wherein the device is configured to receive instructions from a user device via infrared communication.

8. canceled.

9. The light emitting device of claim 6, wherein the instructions specify one or more of:
i) a time period during which the at least one light source should be on;
ii) a time period during which the at least one light source should be off;
iii) an intensity of light to be emitted from the at least one light source;
iv) a wavelength of light to be emitted from the at least one light source; and
v) a polarisation of light to be emitted from the at least one light source.

10. The light emitting device of claim 6, wherein the light emitting device further comprises:
a light emission selection algorithm stored in the memory, the algorithm configured to select one or more output parameters of the at least one light source based on the instructions;
wherein the instructions comprise at least one of:
i) one or more species of ocean organism to be targeted; and
ii) expected fishing conditions.

11. The light emitting device of claim 1, wherein the power source is:
(i) wirelessly chargeable; and/or
(ii) configured to provide power to the at least one light source only when the light emitting device is submerged in seawater.

12. The light emitting device of claim 11, further comprising:
a capacitive sensor enclosed within the first housing portion;
wherein the power source is configured to provide power to the at least one light source only when a capacitive measurement obtained by the capacitive sensor indicates that the light emitting device is submerged in seawater.

13. The light emitting device of claim 1, wherein the light emitting device is configured to attach to a fishing device.

14. The light emitting device of claim 13, further comprising an attachment configured to attach the light emitting device to a fishing device or further comprising an attachment configured to attach the light emitting device to a fishing device where the attachment is a sprung clip and the sprung clip is removably attachable to the light emitting device.

15. canceled.

16. The light emitting device of claim 1, wherein the light emitting device is configured to selectively emit light in at least one of:
a first direction; and
a second direction antiparallel to the first direction.

17. The light emitting device of claim 1, wherein the second housing portion is configured to prevent ingress of water at depths of up to 1000 m.

18. A system comprising a plurality of light emitting devices according to claim 1.

19. The system of claim 18, wherein the plurality of light emitting devices are configured to emit light cooperatively or wherein the plurality of light emitting devices are configured to emit light cooperatively to produce at least one of:
(i) a temporal pattern;
(ii) a colour pattern; and
(iii) a spatial pattern.

20. canceled.

21. The system of claim 18, further comprising:
a user device, the user device comprising a user interface configured to enable a user to select instructions to control each of the plurality of light emitting devices;
wherein the user device is configured to communicate instructions to the memory of each of the plurality of light emitting devices via wired or wireless communication.

22. The system of claim 21, wherein the user device is configured to communicate instructions to the memory of each of the plurality of light emitting devices via infrared communication and/or wherein the instructions specify one or more of:
(i) a time period during which the at least one light source of each of the plurality of light emitting devices should be on;
(ii) a time period during which the at least one light source of the each of the plurality of light emitting devices should be off;
(iii) an intensity of light to be emitted from the at least one light source of each of the plurality of light emitting devices; and
(iv) a wavelength of light to be emitted from the at least one light source of each of the plurality of light emitting devices.

23. canceled.

24. The system of claim 18, further comprising:
a wireless charging module configured to wirelessly charge at least a subset of the plurality of light emitting devices simultaneously and, optionally or preferably, wherein the wireless charging module may comprise a plurality of recesses, each of the plurality of recesses configured to receive at least one of the plurality of light emitting devices during wireless charging of at least a subset of the plurality of light emitting devices.

25. The system of claim 24, wherein the wireless charging module is configured to wirelessly charge at least a subset of the plurality of light emitting devices simultaneously using the Qi wireless charging protocol.
